(19) United States
(12) Patent Application Publication
(10) Pub. No.: US 2024/0322790 A1
(43) Pub. Date: Sep. 26, 2024

(54) Overmoded Bulk Acoustic Resonators and Method of Fabricating

(71) Applicant: CARNEGIE MELLON UNIVERSITY, Pittsburgh, PA (US)

(72) Inventors: Zachary Schaffer, Pittsburgh, PA (US); Gianluca Piazza, Pittsburgh, PA (US)

(73) Assignee: CARNEGIE MELLON UNIVERSITY, Pittsburgh, PA (US)

(21) Appl. No.: 18/614,849

(22) Filed: Mar. 25, 2024

Related U.S. Application Data
(60) Provisional application No. 63/454,207, filed on Mar. 23, 2023.

(51) Int. Cl. H03H 9/17; H03H 9/02; H03H 9/56

(52) U.S. Cl. CPC H03H 9/17; H03H 9/02015; H03H 9/566

(57) ABSTRACT

Disclosed herein is an Overmoded Bulk Acoustic Resonator (OBAR) and a solidly-mounted OBAR (SBAR), which operate in a partially transduced 2nd overtone split between piezoelectric and electrode layers using dual all metal Bragg mirrors. The devices may be deployed in a series configuration. The devices have arbitrarily thick electrodes to minimize ohmic loss and bandwidths high enough to meet filtering requirements of 5G networks. The devices provide sharp filtering which can be performed directly at each antenna element in a form factor much smaller than the half-wavelength separation between adjacent antenna elements required when using electromagnetic resonators.

### RELATED APPLICATIONS

This application claims the benefit of U.S. Provisional Patent Application No. 63/454,207 filed Mar. 23, 2023, the contents of which are incorporated herein in its entirety.

### GOVERNMENT INTEREST

This invention was made with U.S. Government support under contract HR0011-22-2-0026, awarded by the Defense Advanced Research Projects Agency (DARPA). The U.S. government has certain rights in this invention.

### BACKGROUND OF THE INVENTION

Demand for wireless data is growing at an astounding rate of up to 30% per year. Current wireless infrastructure cannot accommodate this growth rate. The 5th Generation (5G) cellular network technology is meant to address these needs by enabling communication data links in the millimeter wave (mmW) range (typically in the range of 30 GHz to 60 GHZ) using phased arrays. The way we communicate has been revolutionized by 5G technology by facilitating high speed data links for augmented and virtual reality, unmanned air vehicles and self-driving cars, remote health and infrastructure monitoring and the Internet of Everything. As the number of deployed 5G systems increases, the number of bits required by the baseband analog-to-digital converter (ADC) of each channel (or element in the phased array) is limited by interference levels. Filtering will thus be essential in limiting the power consumption of ADCs for each element in the phased array as well as reducing the linearity requirements on the amplifiers. The need for mm-wave filtering will be a fundamental bottleneck to further deployment of 5G networks.

Commercial solutions for 5G phased arrays use a combination of RF and digital beamforming technologies. For both, it is likely that the main bottleneck for large scale roll out will be the ability to suppress interferers. The number of bits required by baseband analog-to-digital converters (ADCs) for each element in the array will likely not be limited by signal to noise ratio (SNR), typically <0 dB, but rather by high interference levels. To suppress these interferers, high performance filters at the antenna level will be required. Although these filters are not used in current implementations, as the mmWave spectrum becomes more and more crowded, the number of interferes will increase and so will the requirements for filtering. These filters are necessary to keep power consumption on the per element ADCs reasonable (by limiting the number of bits), as well as minimize amplifier linearity requirements. Phased arrays with per element filtering require filters much smaller than the half-wavelength separation of the adjacent phased array antenna elements.

While other approaches for performing filtering functions at mmWave frequencies have been demonstrated, these techniques are all based on the use of electromagnetic resonators. Regardless of whether waveguide resonators, low-temperature co-fired ceramic cavity resonators, loaded cavity resonators, microstrip filter resonators, or laminated core resonators are used, the filter dimensions are fundamentally limited by the size of the electromagnetic wavelength at these frequencies. The smallest demonstrated filters for mmWave range far exceed the required half EM wavelength spacing, making them impractical for use at each antenna element (which are also generally spaced by ½ of the electromagnetic wavelength). Acoustic resonators, due to their much lower phase velocity (a few thousands m/see for acoustic waves vs. ˜10⁸ m/sec for electromagnetic waves), enable extremely small form factors, potentially only a few microns on a side per device), allow insertion past each antenna element and enable extremely small form factors at mm-waves (potentially only a few microns on a side per device) and are likely to be the only viable approach for the implementation of direct filtering at each antenna element in a phased array.

The design of an acoustic resonator should achieve the following goals: 1) attaining a high electromechanical coupling, which facilitates the synthesis of low loss and wideband filters; 2) achieving high quality factor (Q) to minimize filter losses and ensure steep roll-off; and 3) demonstrating impedances matched to 50Ω in a small form factor so as to minimize the need for external matching components. Earlier work on 10-50 GHz acoustic resonators has shown that it is feasible to demonstrate vibrating mechanical devices operating in the mm-wave frequency range. Work on piezoelectric aluminum nitride resonators shows that 28 GHz resonators can be demonstrated in nanoscale films and very small form factors (i.e., just few microns on a side). These devices could be matched to 50Ω but suffer from relatively large losses and demonstrated Qs below 200, making them far less competitive with respect to alternative electromagnetic-based filtering technologies in terms of resulting filter losses and roll-off. Works by the MEMS community have confirmed that aluminum nitride films or doped films can operate at these frequencies and in topologies which support either higher quality factors (Q˜500) or a large electromechanical coupling coefficient (kₜ²) of around 10%. The integration of resonators in advanced CMOS processes has facilitated the insertion of innovative phononic crystal designs into electrostrictive acoustic resonators, which have exhibited exceptionally high-Q (i.e., in excess of 10,000) at mm-wave frequencies. The low kₜ² intrinsic to the electrostrictive transducer renders the device characteristic impedance very high and, most importantly, limits the attainable filter bandwidth, making such devices impractical for 5G filtering applications.

However, high-Q at mm-wave is possible. The exploration of alternative ferroelectric thin films made available by atomic layer deposition, such as HfO₂, have enabled the demonstration of mm-wave vibrations in various resonator geometries. Despite this progress, these devices still suffer from large impedances and high losses, limiting their Qs to be below 300 at the highest frequencies. Other works on over-moded acoustic resonators in thin films of lithium niobate has shown that such devices can support frequencies up to 50 GHz with Qs on the order of a few 100s. Despite the acceptable electromechanical coupling, the method of excitation of these modes of vibrations make it impractical to attain the desired characteristic impedances in a competitive form factor or ways that would ensure accurate frequency setting.

### SUMMARY OF THE INVENTION

Disclosed herein is an Overmoded Bulk Acoustic Resonator (OBAR) and a solidly-mounter OBAR (SBAR), which operate in a partially transduced 2nd overtone split between piezoelectric and electrode layers, and which use dual all metal Bragg mirrors and series arrays of devices. The devices have arbitrarily thick electrodes to minimize ohmic loss and bandwidths sufficient to meet filtering requirements. The devices provide sharp filtering which can be performed directly at each antenna element, in a form factor much smaller than the half-wavelength separation between adjacent antenna elements required when using traditional acoustic resonators.

The disclosed device, fabricated by the disclosed method, mitigates the scaling challenges encountered in other bulk acoustic resonator technologies by allowing arbitrarily thick metal electrodes, a piezoelectric layer 2× thicker, and electromechanical coupling coefficients (kₜ²) in excess of 10%. This is achieved through 3 main design/fabrication features. First, the device operates in an overtone which confines energy in the piezoelectric layer. Second, a metal Bragg mirror is used to confine energy as well as minimizing series resistance losses and facilitating routing. Third is the integration of high coupling Y-36 LN layers by means of a layer transfer process.

A Solidly Mounted OBAR, referred to herein as “SBAR”, consists of a piezoelectric layer sandwiched between two all metal Bragg mirrors, encapsulation and interconnects. The SBAR functions in a 2nd overtone. However, instead of confining acoustic energy solely to the piezoelectric layer, the mode is split between the piezoelectric layer and each electrode. The piezoelectric layer and each electrode have thicknesses equal to ½ the acoustic wavelength (λ), leading to a mode shape within the transduced region (piezoelectric layer) similar to a fundamental thickness extensional mode. This prevents the typical problem of overtones in which regions of expansion and contraction produce positive and negative polarizations which cancel, reducing kₜ². This design allows ˜⅔ the kₜ² of a fundamental thickness extensional mode.

Exemplary embodiments of the OBAR are fabricated using a 5-step process shown in FIG. 11 and the SBAR devices are fabricated using a 9-step process shown in FIG. 13. The fabrication process is discussed in detail in the Detailed Description section herein.

### BRIEF DESCRIPTION OF THE DRAWINGS

FIG. 1 is a schematic representation of the acoustic cavity for a 1D thickness extensional mode showing stress for fundamental, 1st overtone, and 2nd overtone.

FIG. 2 shows 1D thickness extensional mode showing stress and piezoelectric charge generation for fundamental, 1st overtone, and 2nd overtone modes.

FIG. 3 shows 1D thickness extensional mode showing stress and piezoelectric charge generation for fundamental, fully transduced 2nd overtone, and partially transduced 2nd overtone modes.

FIG. 4 shows fundamental and partially transduced 2nd overtone mode for an Aluminum Nitride (AlN) uniform acoustic property stack consisting of an electrically piezoelectric and conductive region, showing stress distribution and electrode to piezoelectric layer ratio (re-ρ).

FIG. 5 shows the results of FEA study sweeping electrode to piezoelectric ratio to determine kₜ². The stack is composed a piezoelectric layer with AlN properties and a conductor layer with the stiffness and density of AlN but instead of piezoelectric properties is an ideal conductor. Note that the optimal ratio of electrode to piezoelectric material allows enhanced kₜ².

FIG. 6 shows the results of an FEA study scaling either acoustic impedance (Z) or phase velocity (vₚₕₐₛₑ) while fixing the other. This is implemented relative with scaling relative to AlN by scaling material density and stiffness. Graph shows optimal electrode to piezoelectric layer ratio (re-ρ) for maximum kₜ² vs. relative scaling of Z or vₚₕₐₛₑ.

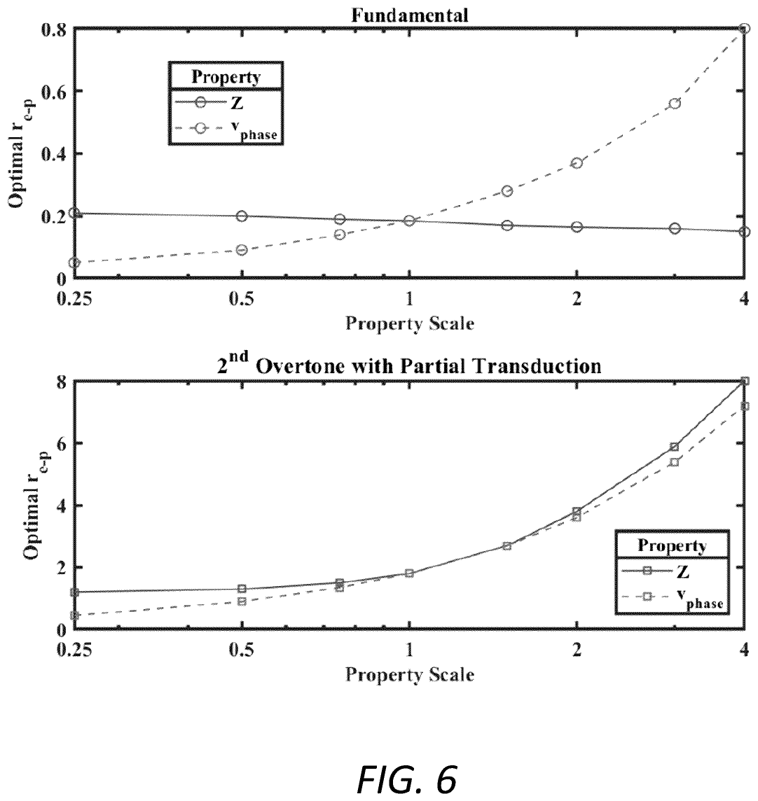

FIG. 7 shows the partially transduced 2nd overtone mode for a stack with AlN piezoelectric layer, inner low acoustic impedance (Z) metal, and outer high Z metal, showing stress distribution and electrode to piezoelectric layer ratio (re-ρ). Note the low Z Al, layered with high Z W, flattens the modeshape relative to the uniform.

FIG. 8 is a schematic showing single vs quad series array with 500 characteristic impedance implemented in Lithium Niobate, providing increased device area for quad series array.

FIG. 9 is a schematic showing acoustic cavity definition for released and solidly mounted resonators.

FIG. 10 is a schematic showing Bragg mirror model with incident wave and absorbing layer, overlayed with stress distribution.

FIG. 11 shows steps of the OBAR fabrication process.

FIG. 12 is an isometric 3D rendering of an OBAR with cutaway cross section views colored by 1 material, 2 local strain, 3 polarization.

FIG. 13 shows steps of the SBAR fabrication process.

FIG. 14 is a schematic of an SBAR showing isometric view of an 8X series arrayed device, dual Bragg mirrors encapsulated by thick metal interconnects confining stress, and the SiO₂/BCB/SiO₂ low loss substrate used for layer transfer process.

FIG. 15 is a flowchart showing the SBAR Fabrication process.

### DETAILED DESCRIPTION

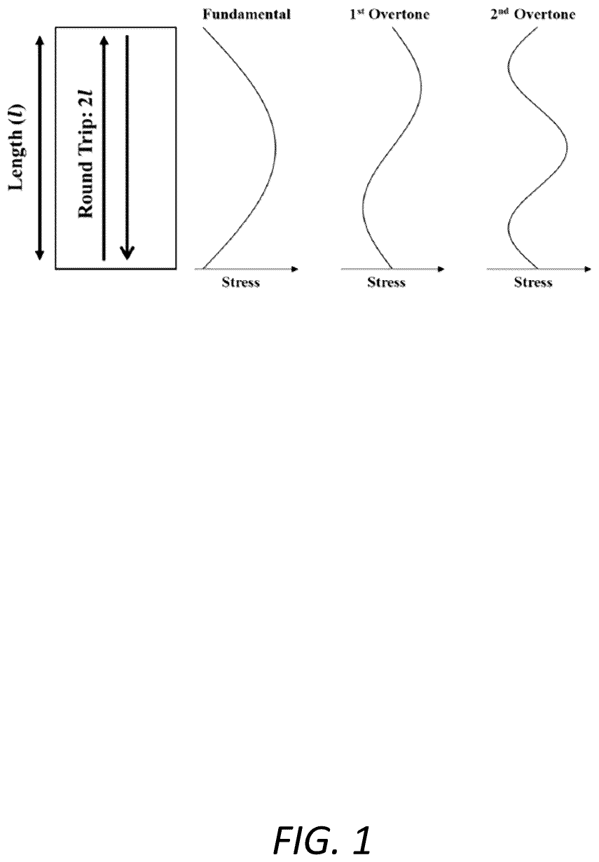

In an acoustic resonator, resonance occurs when a mechanical stimulus is applied at a specific frequency so that it adds constructively to build up a standing wave. The fundamental frequency for an acoustic resonance is determined by the wave's phase velocity (vₚₕₐₛₑ) and the round trip path length which, in the case of a thickness mode, is 2 times the thickness, as shown in FIG. 1. If the stimulus is applied at higher multiples of the fundamental frequency, overtones are created as shown below. Using Eq. (1), the fundamental mode is referred to as n=0 and the 2nd overtone as n=2. It can be helpful to compare the frequency ratio between the fundamental and target overtone to ensure understanding of the mode.

$${f}_{n} = ( n + 1 ) \cdot \frac{1}{2 l} {v}_{phase}$$

Overtones allow a higher resonant frequency in the same size acoustic cavity, making it an attractive approach for scaling to mmWave acoustic resonators. Using a piezoelectric material allows conversion between electrical and mechanical domains with an electromechanical coupling coefficient (kₜ²) dependent on the piezoelectric properties of the material. Exciting an overtone instead of the fundamental mode reduces kₜ². In a uniform piezoelectric material, only even overtones can be transduced as the charge generated in odd modes fully cancels. For the even modes, kₜ² reduces quadratically as shown in Eq. (2):

$$\frac{{k}_{{t}_{n}}^{2}}{{k}_{{t}_{fundamental}}^{2}} = \frac{1}{{( n + 1 )}^{2}} for even n \qquad ( 2 )$$

where n is the overtone number

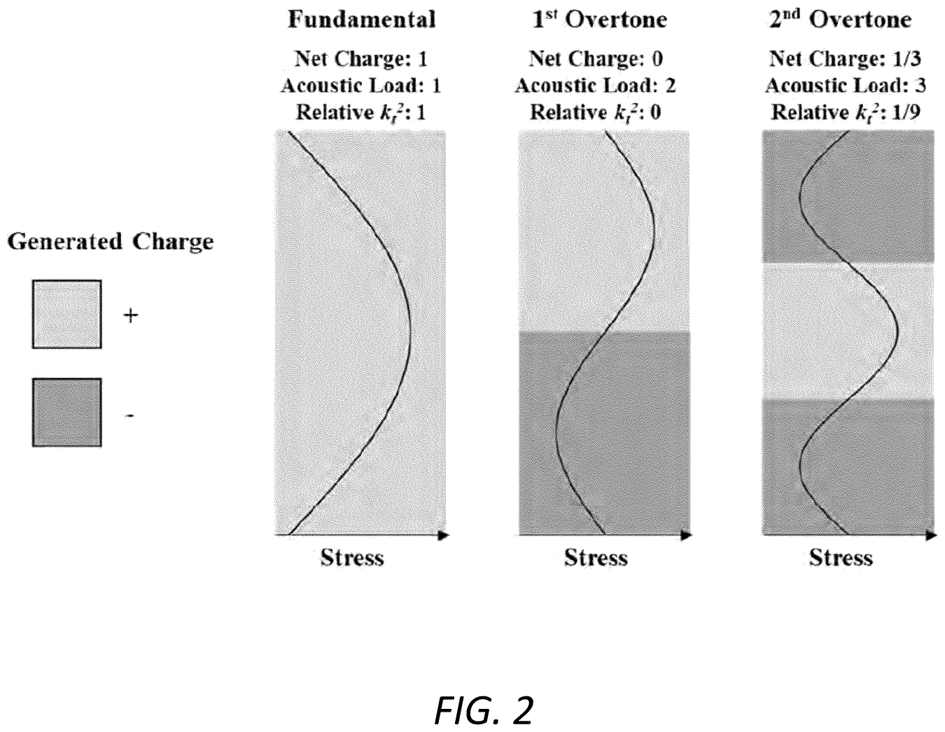

This is caused by both increased acoustic load and cancellation of charge from out of phase nodes. For a second overtone in a uniform piezoelectric material, kₜ² is 1/9 of the fundamental mode, as shown in FIG. 2. This device kₜ² is too low for many filter applications.

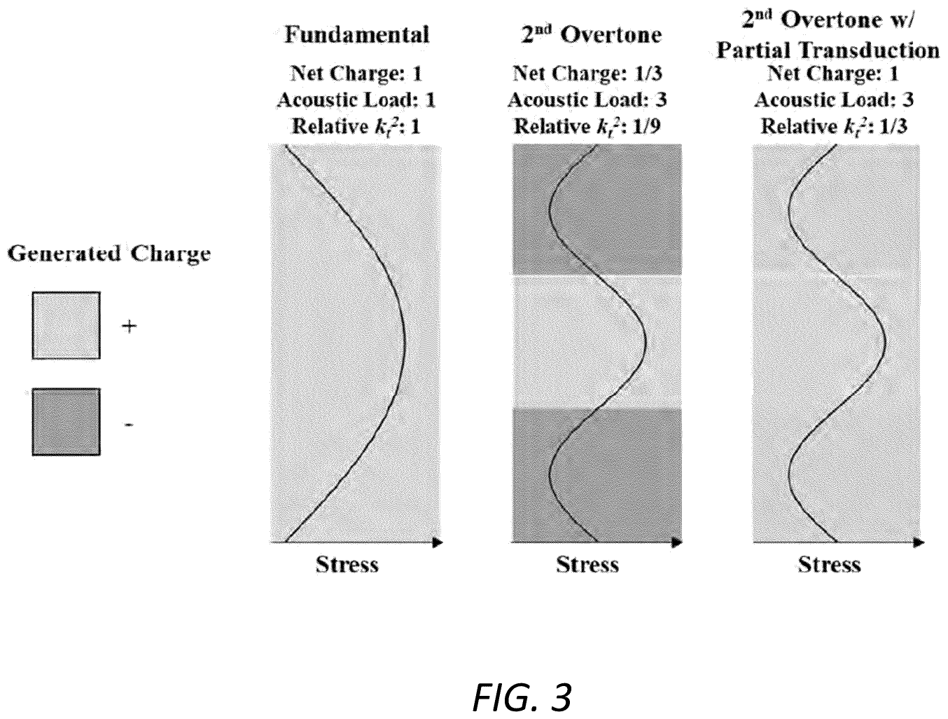

The OBAR functions in a 2nd overtone, but instead of confining acoustic energy solely to the piezoelectric layer, the mode is split evenly between the piezoelectric layer and each electrode. The piezoelectric layer and each electrode have thicknesses equal to ½ the acoustic wavelength (λ), causing only the center node to be in the transduced region (piezoelectric layer), leading to a transduced mode shape similar to a fundamental mode. This prevents the typical problem of overtones in which regions of expansion and contraction produce positive and negative polarizations, which cancel net charge, thereby reducing kₜ². Assuming uniform acoustic properties and layer thickness, kₜ² is ⅓ of the fundamental mode as shown in FIG. 3.

This can be further improved to ⅔ of the fundamental mode kₜ² by optimizing layer thickness and material selection. To understand this impact, it is helpful to evaluate materials based on acoustic impedance (Z) and acoustic phase velocity (vₚₕₐₛₑ) as defined in Eq. (3)-(4) based on density (ρ) and Young's modulus (E):

$${v}_{phase} = \sqrt{\frac{E}{ρ}} \qquad ( 3 )$$

$$Z = \sqrt{E \cdot ρ} \qquad ( 4 )$$

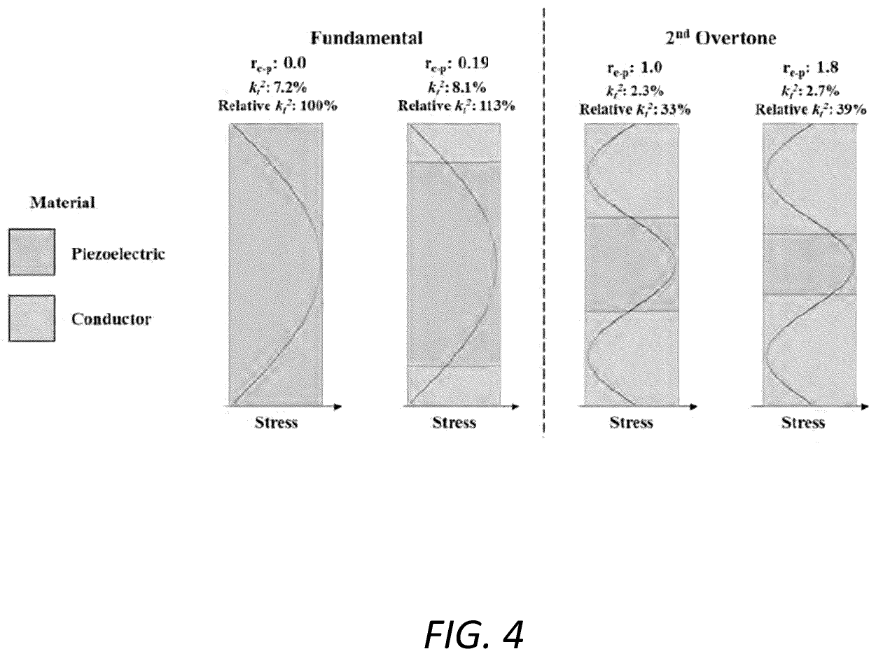

To have a second overtone where one node is present in each layer requires equal effective path length which can be determined by layer thickness and the propagation speed (c) through the layer. Therefore, using slower phase velocity materials results in higher thicknesses. kₜ² is a function of how much charge is captured from the transduced region. Charge density is not uniform, but rather sinusoidal with a maximum in the center. Therefore, not transducing the outermost edges of the mode enhances kₜ². The mode can be simulated in an infinitely wide plate using 2D COMSOL Finite Element Analysis (FEA) simulations. In this simulation the center “piezoelectric” layer is AlN and the outer “electrode” layer modeled as a perfect conductor. Therefore, only the center piezoelectric layer generates and transduces charge. In this simulation, all layers have the same vₚₕₐₛₑ and Z. By increasing the ratio of electrode to piezoelectric region (re-ρ), so that only ⅔s of the center node is transduced. kₜ² is improved from 2.3%-2.7%. Compare this to the 7.2% kₜ² of a fundamental mode pure AlN to give relative kₜ² of 33% and 38% respectively. FIG. 4 shows the difference in mode shape, and the relation between re-ρ and kₜ² for a uniform acoustic property stack.

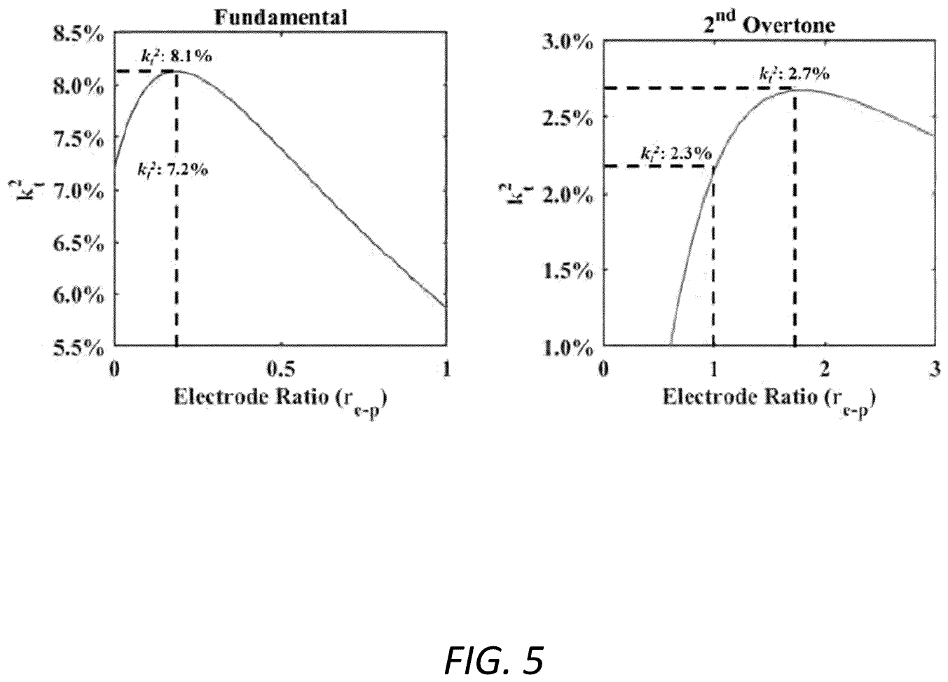

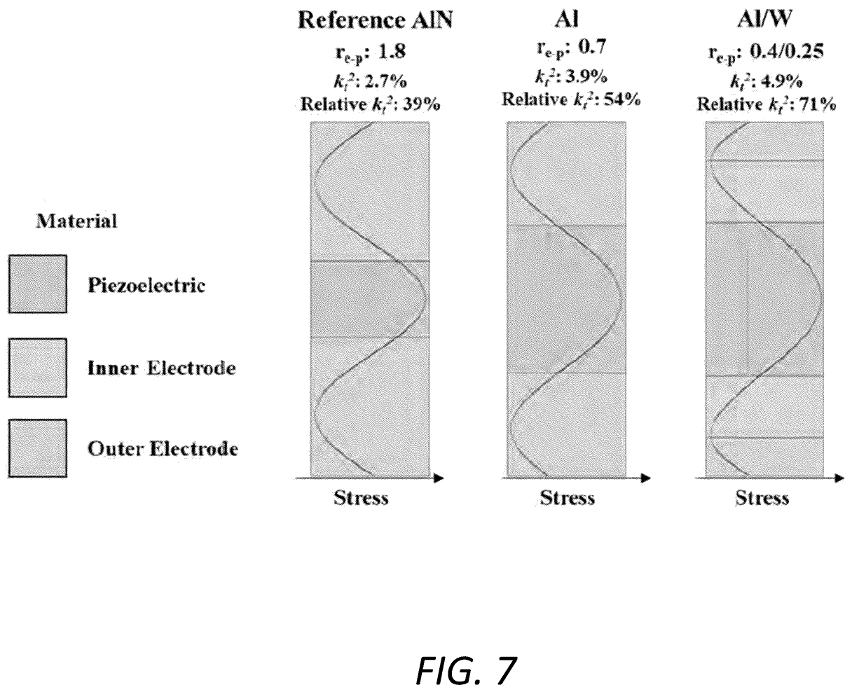

kₜ² can be enhanced much further by using a low Z material to decrease acoustic loading from the electrodes. The stiffer and lighter the better, with an unphysical material with 0 Z adding no load and allowing the full kₜ² of the fundamental mode. Using the same 2D FEA simulations, the p and E of AlN can be scaled to sweep vₚₕₐₛₑ or Z, related by Eq. (3) and Eq. (4), while keeping the other constant. For each point in these simulations, a secondary sweep of re-ρ can be run to generate curves similar to FIG. 5 and to determine optimal re-ρ and kₜ². It is interesting to note that vₚₕₐₛₑ has no impact on maximum kₜ² but impacts the ratio of layer thicknesses needed to reach it. Instead, maximum kₜ² is determined solely by Z. FIG. 7 shows the results of the simulations with respect to optimal re-ρ and mode kₜ².

The results of all the simulations show that when re-ρ is optimal, low Z metals such as Al and Ti are the best choices. kₜ² can be enhanced to 3.9% with A/electrodes and an AlN center.

This can be taken one step further by replacing the single material electrodes with dual layers consisting of an inner low Z metal, and an outer high Z metal. An outer layer of a high Z metal serves to better confine acoustic energy to the AlN layer as the modeshape is flattened out, causing a better stress distribution within the transduced region. Effectively the same enhancement effect causing kₜ² enhancement in the fundamental mode as shown in FIG. 7.

Using an optimized Al/W pair with AlN, kₜ² can be further increased to 4.9%, ˜⅔ of the fundamental mode. However, using Ti/W allows 4.0% kₜ² and results in a better Q. This is much better than the 2.3%(⅓ fundamental mode) kₜ² achievable from a uniform property and thickness stack.

To avoid the need for external matching networks, the characteristic impedance of a filter needs to be matched to the proceeding and following stages, typically at 50Ω. With respect to an individual resonator, this means that to be matched, the C₀ must have a specific value dependent on the filter center frequency. While some bandpass filter implementations such as ladder filters can use a higher than 1:1 capacitive ratio between shunt and series devices to improve roll off, this ratio does not typically exceed 4, meaning the match capacitance will be within 0.5-2 times the value set by Eq. (5):

$${C}_{0} = \frac{1}{2 π \cdot f \cdot Z 0 \cdot \sqrt{r}} \qquad ( 5 )$$

where:
f is frequency;
Z0 is the characteristic impedance of the system (normally 50Ω); and
r is the capacitive ratio between shunt and series filter elements.

For OBARs, C₀ is formed by two parallel plates which have a separation distance determined by resonant frequency and a dielectric permittivity dependent on the piezoelectric material choice. For a 50Ω match, the separation distance is much smaller than the device area, so the parallel plate approximation in Eq. (6) is reasonable.

$${C}_{0} = \frac{{ε}_{r} \cdot {ε}_{0} \cdot A}{d} \qquad ( 6 )$$

where:
εᵣ is relative dielectric permittivity;
ε₀ is vacuum dielectric permittivity;
A is device area; and
d is separation distance.

Lateral dimensions have an impact on device performance that go beyond the value of C₀. The mode shape has been discussed for infinitely wide cavities. In real devices, lateral dimensions impact mode shape, lowering kₜ² and lowering Q through anchor loss. While techniques such as frames and etch trenches can limit anchor loss, ultimately there is still a proportionality between loss and the vertical to lateral cavity ratio.

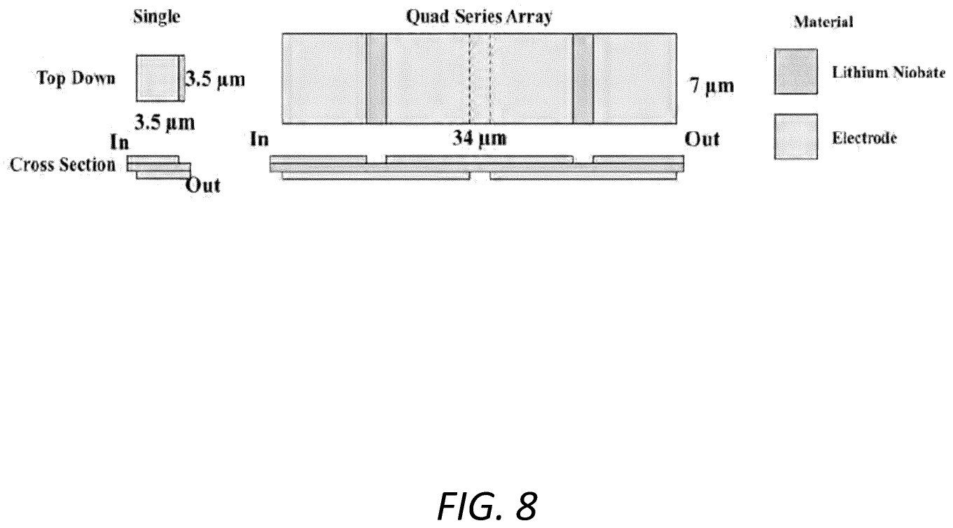

One way around this is to array multiple resonators in series, to allow the use of larger areas while still not exceeding the capacitance requirements. This often presents challenges for device interconnects and large footprints. Using the solidly mounted approach with thick electrodes minimizes ohmic loss tradeoffs, allowing more than 8 series devices with less than 10% ohmic loss for expected upper limits of kₜ² and Q. Using a high dielectric permittivity material like LN and operating at high frequency (thin separation distance) allows small footprints even for large series arrays. A 50Ω matched series array comprised of 4 resonators still occupies less than 250 μm² of area. This has further advantages for power handling, as having multiple resonators in series, as shown in FIG. 8, reduces the electric field across each device.

Films can only be made so thin, and scaling up resonator frequency requires scaling down film thickness. In devices where the metal electrodes are in the path of the acoustic wave, the electrode material and thickness also play a role in setting center frequency. Adjusting the ratio of electrode to piezoelectric thickness (re-ρ) can improve this limit by increasing one layer thickness at the cost of the other. At any given frequency, the OBAR has a 2-3.5 times thicker piezoelectric layer and 5-10 times thicker metal electrodes than a fundamental mode device, allowing practical fabrication of devices in the 30-60 GHz range. Because electrode resistance is inversely proportional to thickness, electrical loading is also greatly reduced in OBAR structures.

In other words, the OBAR allows for the central piezoelectric layer to have the thickness it would in an unmetalized fundamental mode, while possessing metal much thicker than the most metalized thin film bulk acoustic wave resonators.

Beyond manufacturability, thinner metal layers present a series challenge for ohmic loss. Ohmic loss refers to loss caused by the finite conductivity of the metal electrodes. In brief, ohmic loss (R_{S}) is the electrical resistance due to the finite conductivity of metal electrodes, and is proportional to the device geometry as expressed by Eq. (7):

$${R}_{s} ∝ t \frac{l}{w} \qquad ( 7 )$$

where:
t is thickness;
l is length; and
w is width.

The electrical loading (impact on Qs) caused by this resistance is dependent on its ratio to resonator impedance at series resonance. For a resonator matched to a specific Z₀ such as 50Ω, meeting a target kₜ² and Q, this series resonance impedance is frequency independent. Because Rₘ is in this case frequency independent, but Rₛ is inversely proportional to frequency, ohmic loss scales as 1/f.

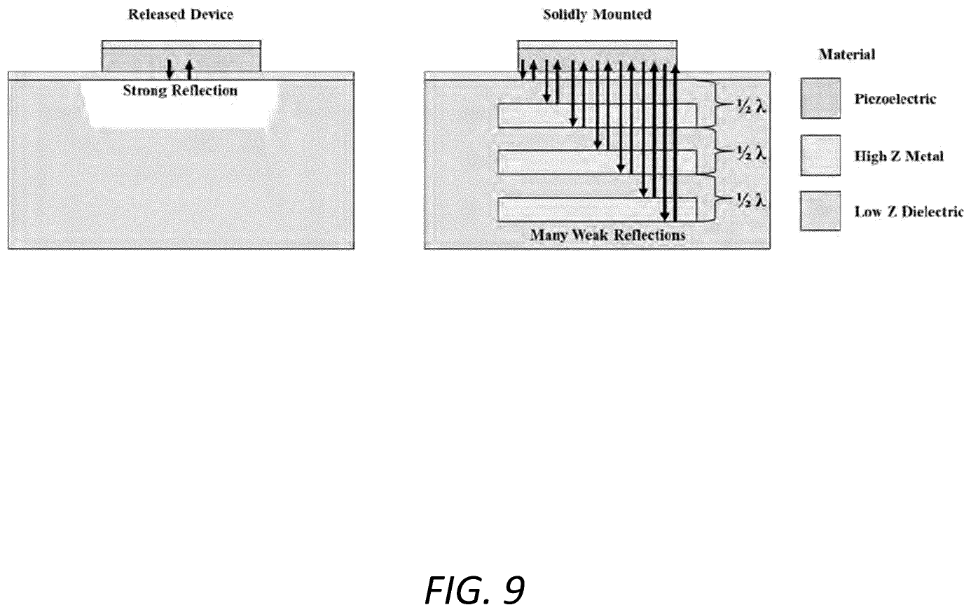

For a resonator to function, an acoustic cavity must be formed with boundaries to reflect elastic waves. To do this, an acoustic impedance mismatch is needed at the cavity edge to reflect energy. The high acoustic impedance mismatch between the solid materials composing a resonator and air is ideal for this and often used to define a resonator's cavity and prevent energy from propagating beyond its boundaries. Energy can instead be confined without an air interface by using the acoustic impedance mismatch between different solid materials. However, this acoustic impedance mismatch is much lower than air, resulting in poor confinement. To improve reflection, Bragg mirrors, also called Bragg reflectors, can be used. Bragg mirrors function using a series of interfaces with mismatched acoustic impedance precisely spaced so that the reflections constructively interfere. A common approach is to alternate ¼ λ thick layers of high and low Z materials, as seen in the FIG. 9. The better the Z mismatch between the materials, the more reflective the Bragg mirror. The reflectivity of the Bragg Mirror can be increased further by adding more layers.

Not releasing the devices has benefits. First, fabrication and packaging can often be simplified if the final structure is not a suspended thin film. Additionally, the robustness of resonators with respect to shock is better when they are not composed of a suspended thin film. Finally, power handling in resonators is often limited by the build-up of heat. Suspended thin films devices must sink heat laterally through the thin film, which has much higher thermal resistance than unreleased devices that sink heat straight down. These stability improvements can be taken further by additionally encapsulating the top electrode.

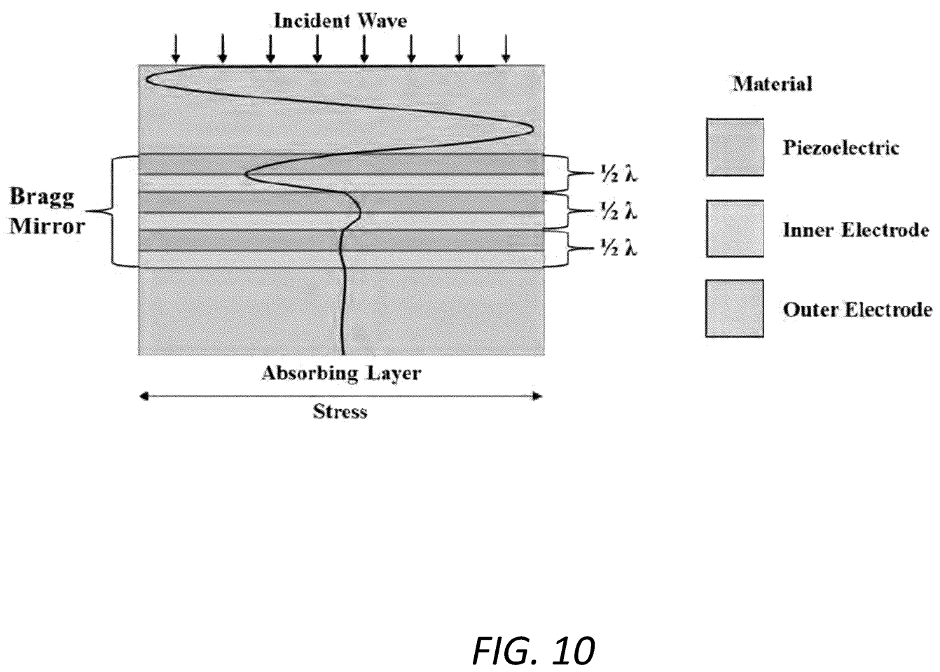

Frequency scaling of thickness mode devices results in extremely thin metal electrodes, which have high ohmic loss. Most Bragg mirror implementations are not conductive. However, some devices have been made using high and low Z metals to form the Bragg mirror. The disclosed device uses top and bottom all metal Bragg mirrors to allow arbitrarily thick metal electrodes, resulting in minimal ohmic loss. Because the separation distance between interfaces is dependent on metal thickness, and to reflect needs to be ¼ λ, reflection is not broadband but rather at specific frequencies. For the SBAR, this is matched to the 2nd overtone within the active region. At the fundamental mode frequency (i.e., ˜⅓ the 2nd overtone frequency), Bragg mirror spacing is too far from ¼ λ to be reflective, suppressing this mode. In other words, the fundamental mode at ⅓ device target frequency is now suppressed by being leaked into the substrate, as shown in FIG. 10. This is advantageous for filter implementations as it results in a resonator with a clean broadband response and no unwanted resonant modes.

The fabrication techniques will now be disclosed in the context of specific, exemplary devices. As would be realized, the invention is not meant to be limited by the specific exemplary embodiments, which are offered only to illustrate the fabrication process. Two embodiments are described, a released OBAR embodiment and a SBAR embodiment.

The fabrication of the OBAR embodiment will now be disclosed. The exemplary device is a released OBAR functioning at 33 GHz. The device exhibits ˜50Ω matched Pt—AlN—Al OBAR operating at 33 GHz with 1.7% kₜ² and series resonance Q>100.

For the thickness dimension, the stack consists of a 70 nm Pt bottom electrode with 10 nm Cr adhesion layer, 140 nm AlN piezoelectric layer, and 90 nm Al top electrode. While a Pt bottom electrode is suboptimal for kₜ², the process for depositing very thin AlN on Pt layers can be tuned.

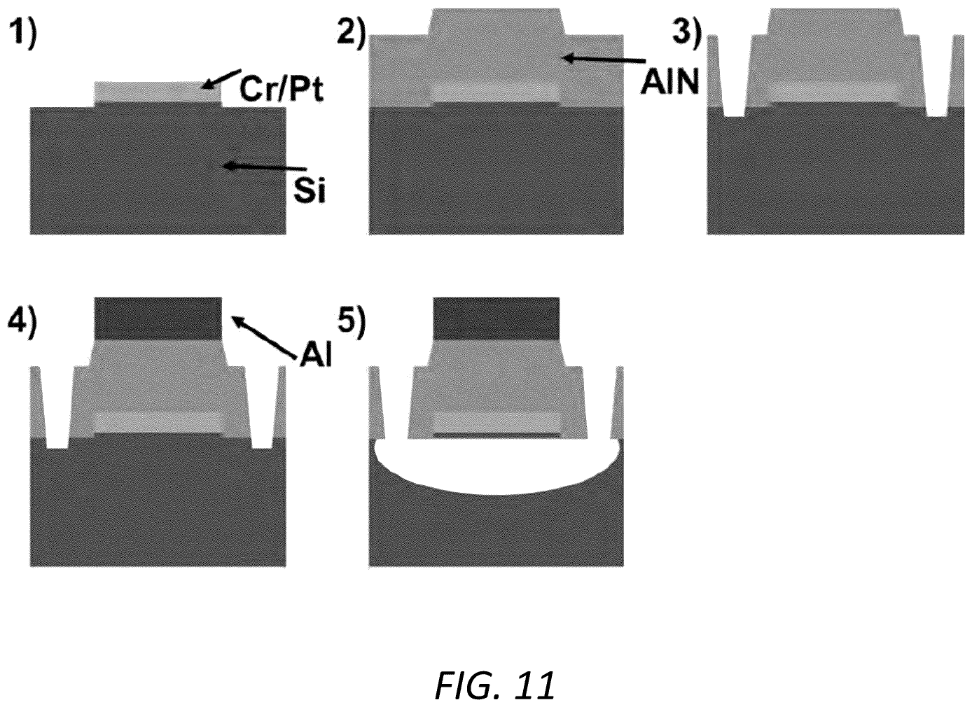

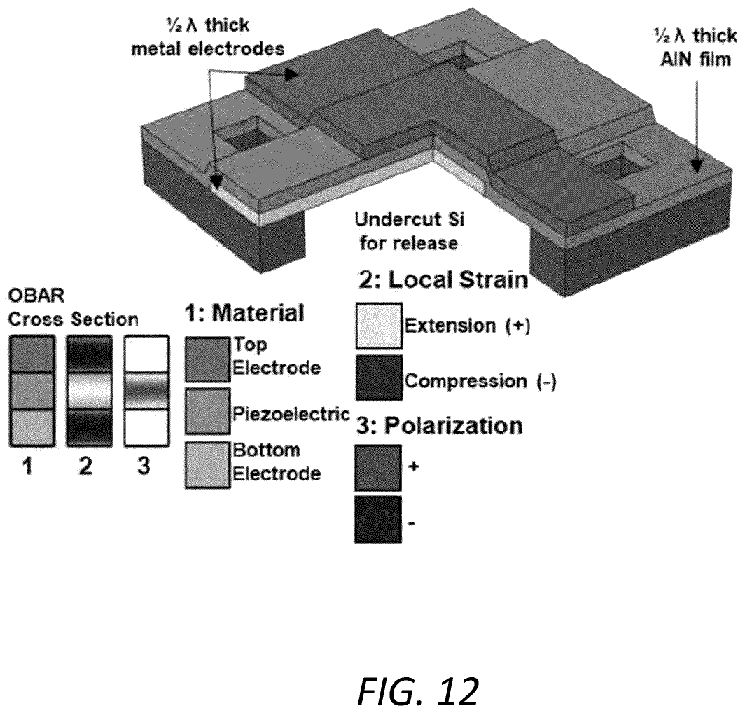

A 3-mask process is used for fabrication as shown in steps (1)-(5) of FIG. 11. In step (1) a 70 nm Pt layer with a 10 nm Cr adhesion layer is blanket DC-sputtered onto a high-resistivity Si wafer to form the bottom electrode. Pattering is then done by ion milling of the Pt and Cr layers with a dielectric mask (e.g., photoresist). This results in a more continuous piezoelectric film, compared to liftoff. In step (2) the piezoelectric material, (e.g., AlN, ScAlN, Ln and many others) is deposited at low power (3 KW) using an AMS sputtering tool. In step (3) the piezoelectric material is wet etched in heated CD26 (TMAH). In step (4) 90 nm of Al is DC sputtered and patterned by liftoff. Finally in step (5) the Si is undercut to release the active region using XeF₂. Note that, because the top and bottom electrodes of this device are routed at 90° instead of 180°, changing aspect ratio increases resistance of one electrode and decreases resistance of the other, making ohmic loss mainly independent of the aspect ratio. For these OBARs this loss is calculated to be <10% of the total loss for the overtone mode. An isometric 3D rendering of the device is shown in FIG. 12.

The fabrication of the SBAR embodiment will now be disclosed. SBAR uses all of the features previously described to implement an implementable mmWave acoustic resonator. First, the active region of the device functions in a 2nd overtone thickness mode split between the piezoelectric and active metal layers. This approach allows a piezoelectric layer thickness almost the same as an unmetallized fundamental mode. Second, the use of optimized active metal layers consisting of a low acoustic impedance inner layer and higher acoustic impedance outer layer allows a kₜ² of almost ⅔ the fundamental mode (˜4.7% for pure AlN, 15.6% for Y-36° LN). Third, the use of all metal Bragg mirrors to define the primary acoustic cavity allows the electrodes to be arbitrarily thick making ohmic loss minimal even for 50Ω matched high kₜ²*Q devices, as well as providing full encapsulation. Fourth and finally, using a layer transfer based fabrication process enables design freedom for choice of materials.

For sputtered films such as AlN or ScAlN this allows optimal selection of seed layer for growth, or in the case of single crystal materials such as Lithium Niobate this allows fabrication of devices starting from commercially available thin films on silicon.

Fabrication plays a critical role for these devices. For optimal kₜ² the metal layer contacting the piezoelectric must be low Z. Based on modeling of the quality factor, Ti appears to be the best choice for this layer, although other metals may be used.

Additionally, roughness of the layers closest to the center piezoelectric has the largest impact on device performance. Instead of attempting to grow high quality AlN on top of a thick metal stack capped by Ti, a layer transfer process is used. This has the added benefit of allowing compatibility with single crystal piezoelectric materials such as Lithium Niobate or Lithium Tantalate which would allow for higher kₜ².

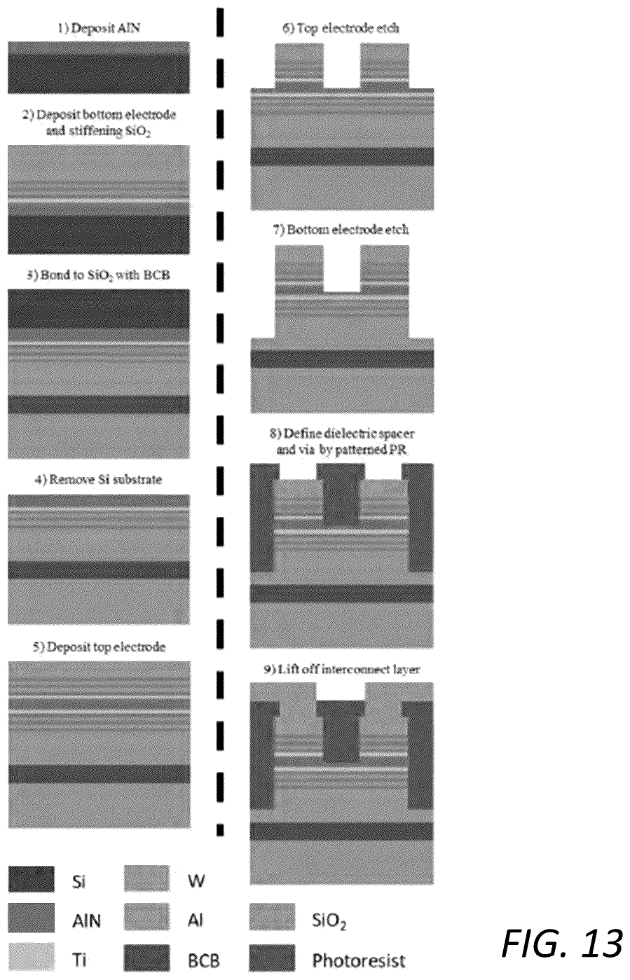

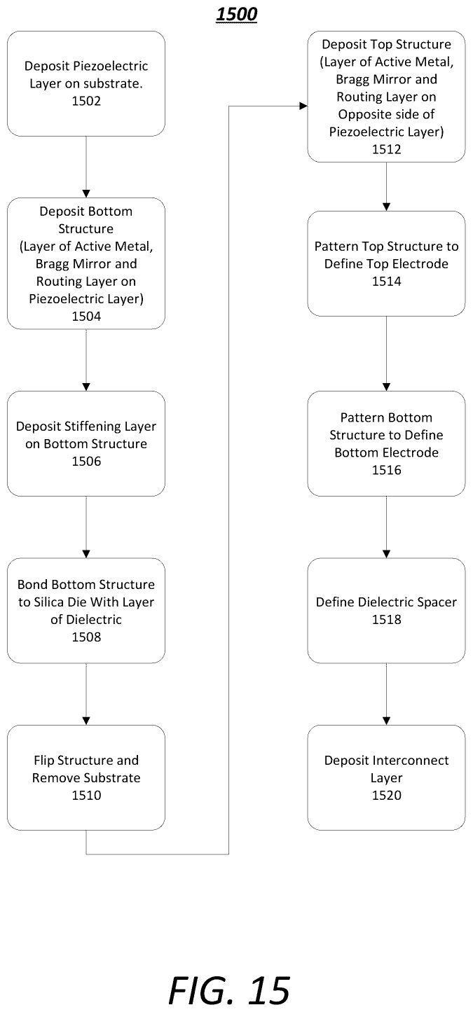

Devices are fabricated using a 9-step, 3-mask process shown schematically in FIG. 13. And in flowchart form in FIG. 15. In step 1502 (1), a layer of a piezoelectric material (e.g., a 110 nm layer of AlN, ScAlN, LN, and many others), is deposited on a substrate (e.g., a Si handler die) in one embodiment using a reactive co-sputter tool with a low power recipe optimized for very thin films. Preferable, yet piezoelectric layer will be ˜½ wavelength in thickness.

In step 1504 (2), the bottom structure is deposited, comprising an active metal layer, an all-metal Bragg mirror and thick routing layer (preferably 400 nm thick Al), which is sputter deposited on the piezoelectric layer, optionally followed by a SiO₂ (1.6 um) stiffening layer at Step 1506. The stiffening layer is extremely useful for preventing the spread of cracks from any bubbles or other defects in the bonding process. The active metal layer is also a low acoustic impedance metal, preferably Ti, which has lower mechanical loss, but higher electrical resistance than Al. Because more mechanical energy is present at the inner layer, using Ti instead of Al will reduce loss in the device (i.e., will improve Q). In other embodiments, other low acoustic impedance materials (e.g., Al) may be used as the active metal layer.

The all-metal Bragg mirrors are composed of multiple mirror pairs comprising alternating layers of a low acoustic impedance metal and a high acoustic impedance metal. In a preferred embodiment, the low acoustic impedance material is Al and the high acoustic impedance metal is W. Each mirror pair (low impedance metal layer and high impedance metal layer) is ˜½ wavelength thick, with each layer being ˜¼ wavelength thick. However, there are other mirror thickness schemes to reflect shear modes. The Bragg mirror may have any number of mirror pairs. Additional reflections from each layer provides better confinement of the acoustic energy, but at a higher fabrication cost.

In step 1508 (3), the initial Si die with deposited layers is flip chip bonded to a new second substrate (glass, silicon, sapphire, silica, etc.) using a dielectric interface layer. Any dielectric material may be used, however, in certain embodiments, divinylsiloxane-bis-benzocyclobutene (BCB) is used for the interface layer. First, both dies are wet cleaned, undergo O₂ plasma barrel ashing, and are then dehydrated in an oven. Then the second substrate is spin coated with 3.8 μm BCB (e.g., Cyclotene 3022-46) and after a 3 minute, 85° C. post application bake, bonded to the initial Si substrate using ramped temperature and pressure in a flip chip bonding tool. The BCB should not be baked in atmosphere to ensure that an SiO₂ layer does not form at the surface, and using ramped temperature and pressure allows formation of a good bond layer with minimal bubbles or cracks. Also, using substrate (e.g., a fused silica handler die) larger than our initial Si die 2.5×2.5 cm vs 1.1×1.3 cm and only spinning BCB on the substrate prevents failed contact due to edge bead effects. After the final hard bake, the BCB is resistant to >12 hour exposure to wet solvents such as acetone, IPA, and 1165 heated to 80° C.

In step 1510 (4), the structure may be flipped for ease of fabrication and the substrate is removed. The Si handler is thinned from 500 to 50 μm using SF₆/O₂ RIE, cleaned of etch residue, and then the final Si is removed using XeF₂ to prevent surface damage to the AlN film. Any remaining F-based residue from the Si can be removed through a wet clean process consisting of immersion in acetone, IPA, then deionized water.

In step 1512 (5), the top structure is deposited comprising an active metal layer, all metal Bragg mirror and a thick routing layer (preferably 400 nm thick Al) which is sputter deposited. Note that it is not necessary that the Bragg mirrors in the top structure and bottom structure be identical. The Bragg mirrors may be composed of different materials and/or may have different numbers of mirror pairs.

In step 1514 (6), ion milling is used to define the top electrode. Etching is stopped in the middle of the piezoelectric layer to prevent any shorting between top and bottom electrode due to redeposition. Additionally, instead of using a fixed 22.5° angle, the first third of the total etch time is milled at a shallow 45° angle and the final two thirds of the time at a sharp 5° angle to prevent redeposition of material in the trench between series top electrodes. In step 1516 (7), a second ion milling step with the same methodology is used to define the bottom electrode, stopping on the SiO₂ stiffening layer.

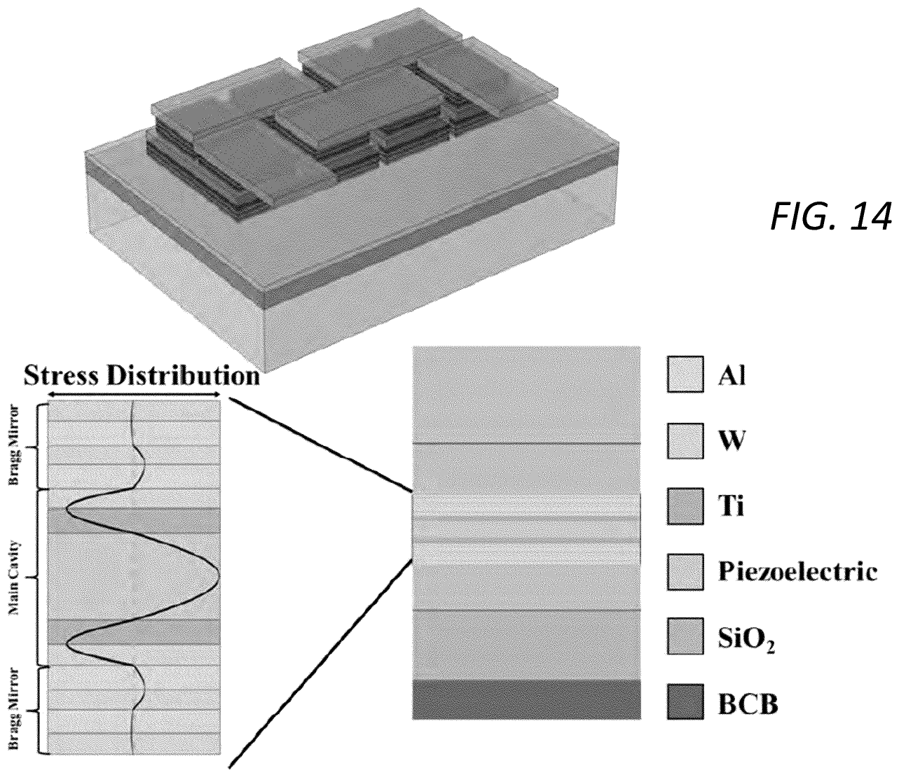

In step 1518 (8), a dielectric material, for example, Photoresist, is used as a planarization and via layer by spinning, pattering, and then hard baking to fully cross link. Finally, in step 1520 (9), a thick (1.5 μm) Al interconnect layer is deposited and patterned using liftoff. This A/layer fills the via holes left in the photoresist, connects devices together for series arrays, and is contacted by probes to allow measurements. Multiple SBAR devices are shown connected in series in schematic and isometric views in FIG. 14.

The disclosed acoustic resonators have a role to play in filtering at mmWave frequencies. While frequency dependence of intrinsic loss mechanisms mean Q of these devices will not equal that of sub-6 GHz resonators, Q requirements are not as stringent for mmWave applications.

The OBAR uses a set of key features including a 2nd overtone thickness mode split between the piezoelectric and active metal layers, series arrays of devices, and all metal Bragg mirrors if solidly mounted to allow a practical to manufacture device capable of meeting kₜ² and Q requirements. kₜ² can be kept up to ⅔s of a fundamental mode meaning up ˜4.7% for pure AlN, and 15.6% for Y-36° LN. The disclosed OBAR device presents a practical approach to acoustic resonator design for mmWave filtering.

As would be realized by those of skill in the art, the specific examples discussed herein have been provided only as exemplary embodiments and the invention is not meant to be limited thereby. Modifications and variations are intended to be within the scope of the invention, which is given by the following claims:

1. A process for fabricating an overmoded acoustic resonator comprising:
depositing a layer of a piezoelectric material on a first substrate;
depositing a first layer of a low acoustic impedance material on a first surface of the piezoelectric layer;
forming a first, all-metal Bragg mirror on the first layer of low acoustic impedance material;
depositing a first routing layer on the first Bragg mirror;
bonding the first routing layer to second substrate using a dielectric material removing the first substrate;
depositing a second layer of a low acoustic impedance material on a second surface of the piezoelectric material opposite the first surface;
forming a second, all-metal Bragg mirror on the second layer of low acoustic impedance material; and
depositing a second routing layer on the second Bragg mirror.

2. The process of claim 1 further comprising:
depositing a stiffening layer on the first routing layer;
wherein the stiffening layer is bonded to the second substrate instead of the first routing layer.

3. The process of claim 1 wherein the first and second Bragg mirrors are formed with alternating layers of a high acoustic impedance metal and a low acoustic impedance metal.

4. The process of claim 3 wherein the high acoustic impedance metal is Tungsten and the low acoustic impedance metal is Aluminum.

5. The process of claim 1 wherein the first and second layers of a low acoustic impedance material are composed of a material selected from a group consisting of Titanium, Aluminum, Chromium and Indium Tin Oxide.

6. The process of claim 1 wherein the dielectric material is BCB.

7. The process of claim 2 further comprising:
milling the second routing layer, the second Bragg mirror and the second layer of a low acoustic impedance material to a level extending into the layer of piezoelectric material to define a top electrode; and
milling the first routing layer, the first Bragg mirror and the first layer of a low acoustic impedance material to a level of the stiffening layer to define a bottom electrode.

8. The process of claim 7 further comprising:
depositing and patterning a layer of a dielectric material to form a planarization and via layer;
depositing and patterning an interconnect layer filling via holes patterned in the dielectric layer.

9. The process of claim 2 wherein the second substrate and the stiffening layer are composed of SiO₂.

10. The process of claim 8 wherein the interconnect layer connects multiple resonators together in series.

11. The process of claim 1 wherein the acoustic resonator is tuned to a specific wavelength, wherein each layer of the first and second Bragg mirrors is approximately ¼ wavelength in thickness and further wherein the piezoelectric layer is approximately ½ wavelength in thickness.

12. A device comprising:
first and second structures, each comprising:
an active layer of metal;
an all-metal Bragg mirror disposed on the active layer of metal; and
a routing layer; disposed on the Bragg mirror opposite the active layer;
wherein the first and second structures are disposed in an opposing configuration having a layer of a piezoelectric material separating the respective active layers of metal.

13. The device of claim 12 further comprising:
a dielectric layer disposed on the routing layer of one of the first or second structures; and
a substrate disposed on the dielectric layer opposite the routing layer.

14. The device of claim 12 further comprising:
a stiffening layer disposed on the routing layer of one of the first or second structures;
a dielectric layer disposed on the stiffening layer; and
a substrate disposed on the dielectric layer opposite the stiffening layer.

15. The device of claim 14 wherein other of the first or second structures is milled to define a top electrode and further wherein the one of the first or second structures is milled to define a bottom electrode.

16. The device of claim 15 further comprising:
an interconnect layer disposed on the top electrode.

17. The device of claim 16 wherein the interconnect layer connects multiple devices together in series.

18. The device of claim 12 wherein the first and second Bragg mirrors are formed with alternating layers of a high acoustic impedance metal and a low acoustic impedance metal.

19. The device of claim 18 wherein the high acoustic impedance metal is Tungsten and the low acoustic impedance metal is Aluminum.

20. The device of claim 12 wherein the active layers in the first and second structures are composed of a material selected from a group consisting of Titanium, Aluminum, Chromium and Indium Tin Oxide.

21. The device of claim 13 wherein the dielectric material is BCB.

22. The device of claim 12 wherein the device is tuned to a specific wavelength, wherein each layer of the first and second Bragg mirrors is approximately ¼ wavelength in thickness and further wherein the piezoelectric layer is approximately ½ wavelength in thickness.
